(19) United States
(12) Patent Application Publication
(10) Pub. No.: US 2012/0241778 A1
(43) Pub. Date: Sep. 27, 2012

(54) LIGHT-EMITTING DEVICE AND METHOD FOR ASSEMBLING A LIGHT-EMITTING DEVICE

(75) Inventors: Felix Franck, Muenchen (DE); Fabian Reingruber, Muenchen (DE)

(73) Assignee: OSRAM AG, Muenchen (DE)

(21) Appl. No.: 13/500,084

(22) PCT Filed: Sep. 30, 2010
(86) PCT No.: PCT/EP2010/064595

§ 371 Date: Jun. 8, 2012

(30) Foreign Application Priority Data
Oct. 5, 2009 (DE) 10 2009 048 313.6

(51) Int. Cl. H01L 27/15; H01L 33/60

(52) U.S. Cl. 257/88; 438/27; 257/E33.072; 257/E27.12

(57) ABSTRACT

A light-emitting device, including a heatsink arranged at a tip of the light-emitting device, at least one light source, in particular a light-emitting diode, arranged on an underside of the heatsink, and a reflector arranged below the heatsink for reflecting at least some of the light emitted by the at least one light source.

The invention relates to a light-emitting device, in particular a LED light-emitting device, in particular for a use as a LED retrofit lamp. The invention also relates to a method for assembling a light-emitting device.

A number of problems arise in an arrangement of light-emitting diodes (LEDs) in a LED retrofit lamp. The LEDs have a strongly directed emission characteristic, for which reason diffusors are often used in order to homogenize the light by scattering. With this approach the light loses its brilliance, however. A further problem are the high temperatures, which create difficulties primarily for a control or driver electronics circuit. In conventional devices the heatsink encloses the driver electronics and additionally heats the latter.

It is the object of the present invention to avoid at least one of the cited disadvantages and in particular to provide a light-emitting device which, while achieving effective cooling of the light sources and without significantly heating up a driver electronics circuit, enables a more brilliant emission of light.

This object is achieved according to the features of the independent claims. Preferred embodiment variants may be derived in particular from the dependent claims.

The object is achieved by means of a light-emitting device which has a heatsink arranged at a tip of the light-emitting device, at least one light source arranged on an underside of the heatsink, and a reflector arranged below the heatsink in order to reflect at least some of the light emitted by the at least one light source.

The tip may also be referred to as a ‘front’ tip or a front end. Other elements of the light-emitting device (at least in the immediate vicinity) are located ‘behind’, ‘under’ or ‘to the rear’ relative to the tip. Because the heatsink is located at the tip of the light-emitting device, a large part of its surface area is exposed with respect to the environment and may therefore dissipate heat very effectively.

The fact that the at least one light source is arranged on the underside of the heatsink means that it does not emit its light in a forward direction. To the contrary, the at least one light source may emit light substantially toward the rear or backward, i.e. into a backward-directed half-space. The backward-directed half-space may be centered e.g. around a longitudinal axis of the light-emitting device. In other words, the at least one light source may have a main emission direction which runs through the backward-directed half-space, in particular parallel to the longitudinal axis of the light-emitting device. The waste heat generated by the at least one light source in this arrangement is dissipated directly by way of the heatsink through the tip, so a substantial part thereof no longer reaches the driver electronics and consequently may also no longer significantly heat up the latter.

Because the reflector is arranged below the heatsink, the light emitted by the at least one light source may be deflected laterally and even partially obliquely forward or upward, thereby reducing a directional dependence of the light emitted by the at least one light-emitting diode and effecting a spatial homogenization of the light distribution. Said spatial homogenization may also be achieved without use of a diffusor, thereby enabling the brilliance of the light emission to be retained.

The at least one light source may include in particular at least one semiconductor light source, such as at least one laser diode and/or at least one light-emitting diode.

The light-emitting device may have in particular a carrier substrate (for the at least one light source) which is fitted on its front side with at least one light source and which is attached by its rear side to the heatsink. This simplifies production and assembly.

It is an embodiment that the heatsink has a hood-like basic shape, i.e. its outer contours or exterior have or has a substantially spherical dome shape. Even without an additional external cooling structure (which may, however, be present in principle) this produces a large surface area and is suitable in particular for a use of the light-emitting device as a LED retrofit lamp for a headshield incandescent lamp.

In order to allow simple attachment of the at least one light source, the heatsink may have on its inside or underside a flat placement surface for the at least one light-emitting diode, in particular the carrier substrate.

It is another embodiment that the reflector is a specular, in particular mirroring, reflector. By this means the brilliance of the light emission is preserved.

The reflector can lie in particular in the main emission direction of the at least one light source in order to reflect a high proportion of the light generated by the at least one light source.

It is yet another embodiment that starting from the heatsink the reflector becomes laterally wider in the downward direction. This enables a large proportion of the light emitted by the at least one light source to be reflected.

It may be advantageous for a particularly undirected light distribution if the reflector has an at least partially curved reflection surface. The reflection surface may be e.g. parabolically and/or hyperboloidally curved at least in sections. Free-shaped curved reflection surfaces are also possible.

It is yet a further embodiment that the reflector has a maximum width which projects beyond a lateral position of the at least one light source. This enables a particularly large percentage of the light emitted by the at least one light source to be reflected.

It is another embodiment that the light-emitting device has a plurality of light sources which are arranged annularly around the reflector. This enables an emission inhomogeneity to be reduced and a light intensity increased. The plurality of light sources may radiate in particular onto the same reflector and/or have the same main emission direction.

It is also an embodiment that the reflector is an open hollow body, at least at its rear end, preferably at its front end and at its rear end. This enables the reflector to be produced with a low weight. It also allows electrical leads to be passed through the cavity of the reflector, e.g. from a driver electronics circuit positioned at the rear to the at least one light source.

It is furthermore an embodiment that the reflector has a lateral feedthrough opening to the carrier substrate. This enables a power supply lead and/or data cable to be easily routed from the driver electronics to the at least one light source.

The reflector may also be fitted onto a housing or housing part, thereby allowing flexibility in the choice of material, e.g. optimized for an attachment of the reflection surface for the reflector as well as for mechanical stability and low heat conduction for the housing part. For that purpose the reflector is preferably the hollow body which is open on at least one side.

The housing may have e.g. a driver cavity for accommodating the driver electronics and a lamp socket (Edison screw cap, bayonet cap, etc.). The lamp socket may be arranged in particular at a rearward or back end.

The housing may be embodied in particular in two parts. An upper housing part can be joined for example to the heatsink and the reflector. A lower housing part may for example contain the driver cavity or a large part of the driver cavity and the socket. In a development the upper housing part may constitute a cover for the driver cavity.

For ease of assembly, the upper housing part and the lower housing part may be fixed or locked together by means of a snap-fit connection. This may be achieved e.g. by means of one or more locking means and counter-locking means, e.g. snap-fit hooks as locking means and latching recesses as counter-locking means.

It is furthermore particularly preferred that the surface of the reflector is joined to the housing, in particular by its underside over its entire surface area.

Generally, the reflector may be a component produced separately from the housing (e.g. a coated or lacquered casing or solid body). Alternatively, the reflector may be joined to the housing as a single piece, e.g. by means of a reflecting coating or lacquering of the housing. In other words, the housing may then have a reflector function.

It is also an embodiment that the heatsink and the housing may be joined to each other, in particular by means of a screwed connection. This enables a particularly stable light-emitting device to be provided. Alternatively—given appropriate embodiment of the reflector and of the housing—the heatsink may be joined to the reflector and the reflector to the housing.

It is a further embodiment that the light-emitting device has a light-transmissive cover, e.g. a bulb envelope, which at least partially encloses the reflector laterally. In order to maintain the brilliance of the light emission, the cover may preferably be transparent. The cover may, however, also be embodied as slightly diffusely scattering in order to achieve a stronger homogenization of the light distribution while continuing to provide a high brilliance.

It is yet another embodiment that in the joined state the heatsink and the housing retain the reflector and/or the cover. This enables assembly to be achieved particularly easily and with few connecting elements and in few assembly steps.

It is a further embodiment that the light-emitting device is a retrofit lamp, in particular an incandescent bulb retrofit lamp. The incandescent bulb or filament lamp to be replaced may be in particular an incandescent bulb having a headshield (“headshield incandescent bulb”). This type of conventional incandescent bulb has a glass bulb envelope which is mirrored toward the front (i.e. mostly in the main emission direction) and which reflects the luminous flux and permits a lateral exit only.

The object is also achieved by means of a method for mounting a light-emitting device as described hereintofore, wherein the method includes at least the following steps of:
placing the cover in position onto the heatsink,
placing the housing joined to the reflector in position onto the heatsink, and
fixing the heatsink to the housing in such a way that the reflector and the cover are held between the heatsink and the housing.

The placement steps may be carried out in any order here. This enables the reflector, the cover and the heatsink to be fixed by means of a single joining operation, e.g. by means of a screwed connection, thereby simplifying assembly.

For a simple connection of the power supply lead(s) and/or data cable(s), it is an advantageous embodiment that the above sequence is preceded by a step as follows:
attaching at least one electrical lead that has been passed through the housing to the at least one light source, in particular to the carrier substrate fitted with the at least one light source.

The method may furthermore include a preceding step of adhesively bonding the LED module to the heatsink, in particular on the flat placement surface on the inside of the heatsink.

The invention is described in greater detail with reference to an exemplary embodiment taken in conjunction with the following schematic figures. For clarity of illustration reasons, like or like-acting elements may be labeled therein with the same reference signs.

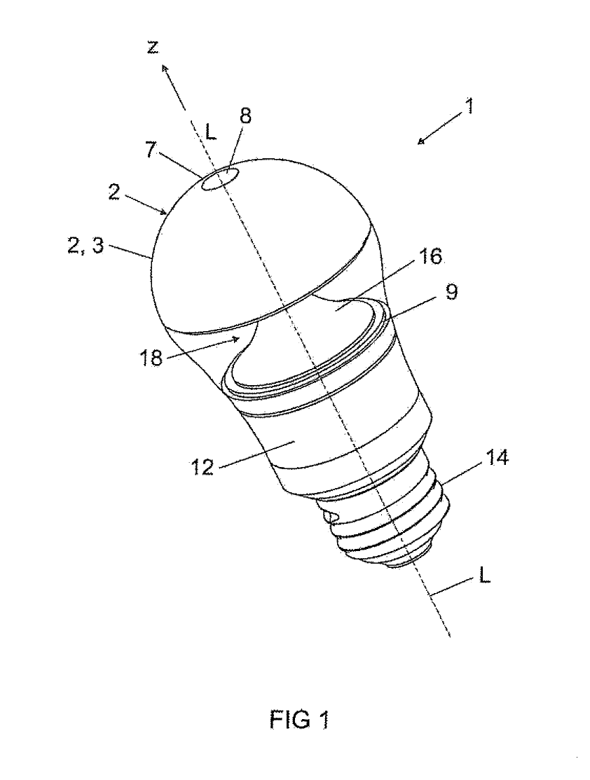

FIG. 1 shows in a lateral oblique view a LED retrofit lamp for replacing an incandescent bulb having a headshield;

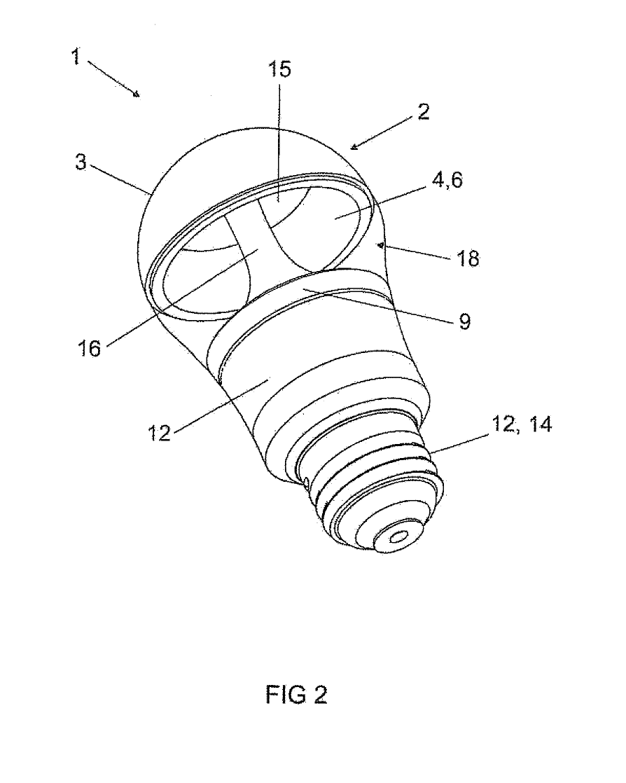

FIG. 2 shows the LED retrofit lamp obliquely from below;

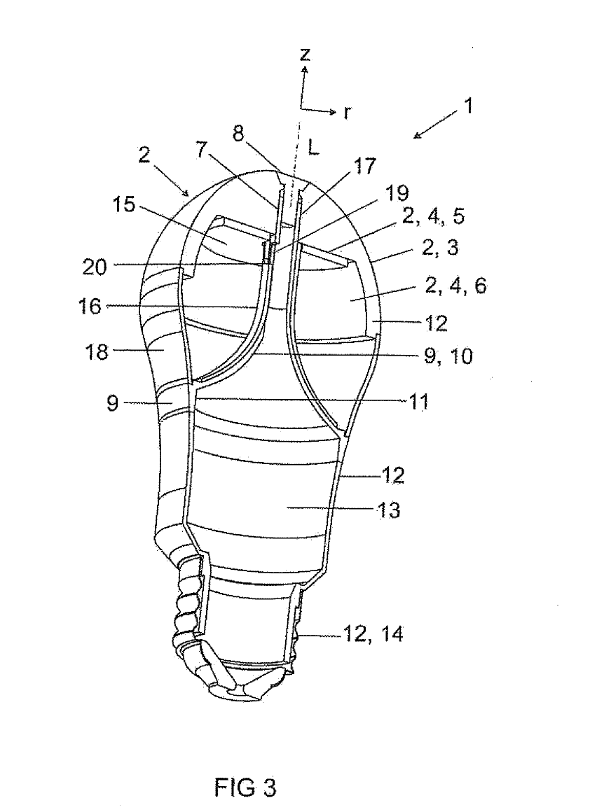

FIG. 3 shows in a lateral oblique view a sectional representation of the LED retrofit lamp;

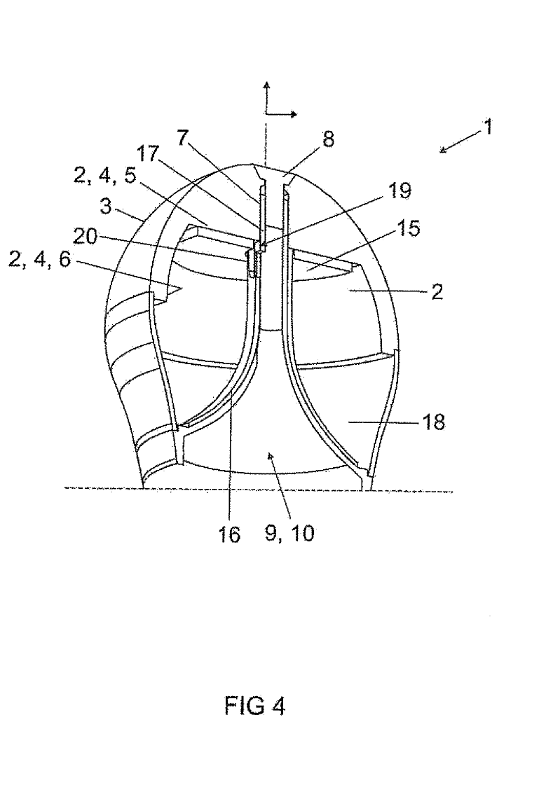

FIG. 4 shows an enlarged detail from the sectional representation from FIG. 3.

The figures show a LED retrofit lamp 1 for replacing an incandescent bulb having a headshield. Located at the front tip or at the front end (which consequently is positioned furthest away in the z-direction) of the LED retrofit lamp 1 is a heatsink 2. The heatsink 2 has a substantially hemispherical exterior 3. In a central region with respect to a longitudinal axis L, an underside 4 of the heatsink 2 has a flat placement surface 5 which transitions at the side into a spherical strip-shaped edge 6. The spherical strip-shaped edge 6 extends laterally and in a backward direction (opposite to the z-direction) beyond the flat placement surface 5.

The heatsink 2 is connected to an upper housing part 9 by means of a screw 8 inserted from outside through a central recess 7 in the tip. The upper housing part 9 is joined to the heatsink 2 from below. Starting from its top end 17, the upper housing part 9 widens out toward the bottom (opposite to the z-direction) laterally (in the r-direction), and moreover with an increasing radius of curvature. This widening section 10 of the upper housing part 9 transitions into an edge region 11 extending rearward and/or downward. The upper housing part 9 is embodied as a hollow body that is open at top and bottom, wherein the top end 17, which is connected by means of the screw 8, may have an internal thread.

The upper housing part 9 and a lower housing part 12 adjoining it at the rear form a housing in which is contained a driver cavity 13. In this arrangement the upper housing part 9 forms a cover for the driver cavity 13. Located in the driver cavity 13 is at least a part of a driver electronics circuit (not shown). Located at a rearward end of the lower housing part 10 is an Edison screw cap 14 for connecting to a corresponding Edison base. The lower housing part 12 is in this case joined to the upper housing part 9 by means of snap-fit latches (not shown).

A ring-shaped LED module 15 including a LED printed circuit board and a plurality of light sources (neither shown explicitly) in the form of light-emitting diodes is fixed, e.g. glued, to the flat placement surface 5. The LED printed circuit board of the LED module 15 is fixed to the flat placement surface 5 by its (upward-directed) back side and fitted on its (downward-directed) front side with a plurality of downward-radiating light-emitting diodes. The top end 17 of the upper housing part 9 protrudes through a central recess of the LED printed circuit board or the LED module 15 into the recess 7 of the heatsink 2 in order to be connected by means of the screw 8.

The light-emitting diodes are arranged annularly around the widening section 10 of the upper housing part 9 with respect to the z-axis or longitudinal axis L. The LED module 15 may additionally be equipped with electronic components, e.g. an electrical resistance or a rectifier diode.

Positioned over the widening section 10 of the upper housing part 9 is a thin-walled reflector 16 which consequently likewise becomes wider laterally in the backward direction, and moreover at the sides (in the r-direction) beyond the position of the light-emitting diodes. As a result the main emission direction of the light-emitting diodes, which in this case lies parallel to the longitudinal axis L, is directed onto the reflector 16, such that the latter reflects a high proportion of the light emitted by the light-emitting diodes. Since the reflector 16 also has an increasingly pronounced curvature as the distance from the light-emitting diodes and the heatsink 2 increases, wide-angle scattering is achieved.

The LED retrofit lamp 1 furthermore has a cover in the form of a transparent bulb envelope 18 running in the circumferential direction which encloses the reflector 16 at least partially at the side. The bulb envelope 18 extends from a bottom edge of the heatsink 2 as far as a lateral edge of the upper housing part 9 below the reflector 16. The bulb envelope is retained there in circumferential annular grooves in each case. The bulb envelope 18 in conjunction with the heatsink 2 and the upper housing part 9 forms a protecting cavity for accommodating the LED module 15 and the reflector 16. With this arrangement the bulb envelope 18 and the reflector 16 do not need to be fixed separately, but are held in position by the upper housing part 9 and the heatsink 2.

Owing to the embodiment of the upper housing part 9 as a hollow body, the interior of the upper housing part 9 can be used as a cable conduit for feeding through at least one electrical lead (cable, wire, etc.) from the driver electronics circuit (which is located in the driver cavity 13) to the LED module 15. In order to allow easy laying and attachment of the at least one electrical lead, a lateral feedthrough opening 19 and 20 is located in the upper housing part 9 and in the reflector 16, respectively. The driver electronics circuit is therefore connected by means of the electrical lead(s) to the LED module 15, in particular the LED printed circuit board, by way of the feedthrough openings 19, 20. It is particularly favorable in terms of ease of assembly that the at least one electrical lead is first attached on the LED module 15, this being followed by the bulb envelope 18, and thereupon the combination consisting of the upper housing part 9 and the reflector 16 are placed in position on the heatsink 2. This is followed by the connection by means of the screw 8.

The LED retrofit lamp 1 shown affords the following advantages, inter alia:

Because the light-emitting diodes and the heatsink 2 are thermally separated from the driver electronics, greater performance classes can be realized.

The light does not have to be distributed via a diffusor, with the result that the light intensity and the quality of the light (brilliance) are not impaired or are impaired only to an insignificant degree.

By means of a different configuration of the reflector it is possible to tailor the emission characteristics precisely to suit different requirements in a simple manner.

It is self-evident that the present invention is not limited to the exemplary embodiment shown.

It is e.g. also possible to install a snap-in engagement position for a small connector at the feedthrough or the mutually overlapping feedthrough openings 19, 20. If corresponding pins are installed on the LED module, in particular on the LED printed circuit board, the construction can simply be clipped together.

The heatsink may also be overarched by the cover.

### LIST OF REFERENCE SIGNS

1 LED retrofit lamp
2 Heatsink
3 Outside of the heatsink
4 Underside of the heatsink
5 Placement surface
6 Edge
7 Recess
8 Screw
9 Upper housing part
10 Widening section of the upper housing part
11 Edge region
12 Lower housing part
13 Driver cavity
14 Edison screw cap
15 LED module
16 Reflector
17 Top end of the upper housing part
18 Bulb envelope
19 Feedthrough opening
20 Feedthrough opening
L Longitudinal axis

1. A light-emitting device, comprising
a heatsink arranged at a tip of the light-emitting device ROM,
at least one light source, in particular a light-emitting diode, arranged on an underside of the heatsink, and
a reflector arranged below the heatsink for reflecting at least some of the light emitted by the at least one light source.

2. The light-emitting device as claimed in claim 1, wherein the heatsink has a hood-like basic shape.

3. The light-emitting device as claimed in claim 1, wherein the heatsink has an exterior shaped substantially like a spherical dome, in particular a hemisphere, and on its underside has a flat placement surface for the at least one light source, in particular a carrier substrate fitted with the at least one light source.

4. The light-emitting device as claimed in claim 1, wherein the reflector is a specular reflector.

5. The light-emitting device as claimed in claim 1, wherein starting from the heatsink the reflector becomes laterally wider in the downward direction.

6. The light-emitting device as claimed in claim 5, wherein the reflector has a maximum width which projects beyond a lateral position of the at least one light source.

7. The light-emitting device as claimed in claim 1, wherein the light-emitting device has a plurality of light sources which are arranged annularly around the reflector.

8. The light-emitting device as claimed in claim 1, wherein the reflector is a hollow body which is open at its top end and at its bottom end.

9. The light-emitting device as claimed in claim 8, wherein the reflector has a lateral feedthrough opening to the at least one light source, in particular to the carrier substrate fitted with the at least one light source.

10. The light-emitting device as claimed in claim 1, wherein the reflector can be fitted onto a housing of the light-emitting device.

11. The light-emitting device as claimed in claim 10, wherein the heatsink and the housing can be joined together, in particular by means of a screwed connection.

12. The light-emitting device as claimed in claim 1, wherein the light-emitting device has a light-transmissive cover which at least partially encloses the reflector laterally.

13. The light-emitting device as claimed in claim 11, wherein in the joined state the heatsink and the housing retain the reflector and/or the cover.

14. A method for assembling a light-emitting device, comprising:
placing a cover in position onto a heatsink,
placing a housing joined to a reflector in position onto the heatsink, and
fixing the heatsink to the housing such that the reflector and the cover are held between the heatsink and the housing.

15. The method as claimed in claim 14 further comprising:
attaching at least one electrical lead that has been passed through the housing to at least one light source, in particular to a carrier substrate fitted with the at least one light source.
